(19) United States
(12) Patent Application Publication
(10) Pub. No.: US 2010/0236478 A1
(43) Pub. Date: Sep. 23, 2010

(54) VACUUM PROCESSING SYSTEM

(75) Inventors: Tetsuya Miyashita, Yamanashi (JP); Noritomo Tada, Yamanashi (JP)

Correspondence Address: CANTOR COLBURN, LLP, 20 Church Street, 22nd Floor, Hartford, CT, 06103, US

(73) Assignee: TOKYO ELECTRON LIMITED, Tokyo (JP)

(21) Appl. No.: 12/676,000

(22) PCT Filed: Aug. 22, 2008
(86) PCT No.: PCT/JP2008/065038

§ 371 Date: Jun. 1, 2010

(30) Foreign Application Priority Data
Sep. 3, 2007 (JP) 2007-227591

(51) Int. Cl. C23C 16/00

(52) U.S. Cl. 118/719

(57) ABSTRACT

A vacuum processing system includes CVD processing chambers to perform a CVD process on a wafer W under a vacuum, and a transfer chamber having loading/unloading holes to load/unload the wafer W and being connected to the CVD processing chambers via gate valves G capable of opening/closing the loading/unloading holes. The transfer chamber includes a transfer mechanism to load/unload the wafer W to/from the CVD processing chambers via the loading/unloading holes and the inside of the transfer chamber is maintained in a vacuum state. The vacuum processing system also includes purge-gas discharge members provided near the loading/unloading holes. In a state where the transfer chamber and any one of the processing chambers are communicated with each other by opening of the gate valve G, the purge-gas discharge member discharges a purge gas to the communicated CVD processing chamber via the loading/unloading hole.

### TECHNICAL FIELD

The present invention relates to a vacuum processing system configured so that a processing chamber is disposed within a transfer chamber capable of being maintained in a vacuum state.

### BACKGROUND

In the fabrication of a semiconductor device, in order to form a contact structure or a wiring structure on a semiconductor wafer (hereinafter, simply referred to as a wafer) as a to-be-processed substrate, a process for forming a plurality of metallic films is carried out. Such a film formation process has been carried out within a vacuum-maintained processing chamber. However, in view of the efficiency in the processing and the suppression of pollution, such as oxidation or contamination, a cluster tool-type multi-chamber system has been recently spotlighted (for example, Japanese Unexamined Patent Publication No. Hei 3-19252). In the cluster tool-type multi-chamber system, a plurality of processing chambers are connected to a vacuum-maintained transfer chamber via gate valves, and a transfer apparatus provided in the transfer chamber can transfer the wafer to each of the processing chambers. In such a system, since a plurality of films can be successively formed without the exposure of a wafer to atmosphere, it is possible to very efficiently perform the process with a small amount of pollutants.

However, when a gate valve is opened to transfer a wafer in a case where a Chemical Vapor Deposition (CVD) processing chamber for performing CVD is connected to the above cluster-tool type multi chamber system, pollutants generated by the CVD, such as unreacted gas or by-product gas, may diffuse into the transfer chamber and other processing chambers, thereby causing cross-contamination.

As a technology of preventing such problems, disclosed is a technology of introducing a purge gas in the transfer chamber and forming a flow of purge gas from the transfer chamber side toward the processing chamber side by allowing a pressure of the transfer chamber to be higher than that of the processing chamber when the to-be-subjected wafer is transferred to the processing chamber (for example, Japanese Unexamined Patent Publication No. Hei 10-270527).

Also, disclosed is a technology of providing an exhaust port near the gate valve of the transfer chamber and rapidly discharging pollutants generated from the processing chamber by locally exhausting from the exhaust port (for example, Japanese Unexamined Patent Publication No. 2007-149948).

However, in the technology of forming the flow of purge gas from the transfer chamber side toward the processing chamber side by a pressure difference, the purge gas is generally introduced from a single portion of the transfer chamber, and thus, the flow of purge gas into the processing chamber has a low density and is likely to be non-uniform. Therefore, it is difficult to sufficiently prevent pollutants from coming in from the processing chamber.

Also, in the technology of providing the exhaust port near the gate valve, since the transfer chamber is in a vacuum state, it is difficult to sufficiently form an exhaust flow. Thus, the effect of this technology is restricted.

### SUMMARY OF THE INVENTION

An object of the present invention is to provide a vacuum processing system which can effectively suppress the diffusion of pollutants from a processing chamber to a transfer chamber.

According to a first aspect of the present invention, there is provided a vacuum processing system. The vacuum processing system includes a processing chamber to perform predetermined processes on a to-be-processed substrate under a vacuum, and a transfer chamber having a loading/unloading hole to load/unload the to-be-processed substrate. The transfer chamber is connected to the processing chamber via a gate valve capable of opening/closing the loading/unloading hole and the inside of the transfer chamber is maintained in a vacuum state. The vacuum processing system also includes a transfer mechanism provided within the transfer chamber to load/unload the to-be-processed substrate to/from the processing chamber via the loading/unloading hole, and a purge-gas discharge member provided near the loading/unloading hole to discharge a purge gas to the processing chamber via the loading/unloading hole in a state where the transfer chamber and the processing chamber are communicated with each other by opening of the gate valve.

The vacuum processing system according to the first aspect may further include a pressure control mechanism to control a pressure of the transfer chamber. The pressure control mechanism may control the pressure of the transfer chamber to be a pressure suitable for the processing chamber. Herein, the pressure control mechanism preferably controls the pressure of the transfer chamber to be higher than the pressure of the processing chamber.

According to a second aspect of the present invention, there is provided a vacuum processing system. The vacuum processing system includes a plurality of processing chambers to perform predetermined processes on a to-be-processed substrate under a vacuum, and a transfer chamber having a plurality of loading/unloading holes to load/unload the to-be-processed substrate. Each loading/unloading hole is connected with each processing chamber via a gate valve capable of opening/closing said loading/unloading hole and an inside of the transfer chamber is maintained in a vacuum state. The vacuum processing system also includes a transfer mechanism provided within the transfer chamber to selectively load/unload the to-be-processed substrate to/from any one of the processing chambers via any one of the loading/unloading holes, a plurality of purge-gas discharge members each provided near each loading/unloading hole to discharge a purge gas toward the corresponding loading/unloading hole, and a control unit to control the purge-gas discharge members so that, in a state where the transfer chamber and said one of the processing chambers are communicated with each other by opening of any one gate valve, the purge gas is discharged from the purge-gas discharge member corresponding to the communicated processing chamber toward the communicated processing chamber via the corresponding loading/unloading hole.

The vacuum processing system according to the second aspect of the present invention may further include a pressure control mechanism to control a pressure of the transfer chamber. The pressure control mechanism may control the pressure of the transfer chamber to be a pressure suitable for the communicated processing chamber from among the plurality of the processing chambers. Herein, the pressure control mechanism preferably controls the pressure of the transfer chamber to be higher than the pressure of the communicated processing chamber from among the plurality of processing chambers.

In the vacuum processing systems according to the first and second aspects, the pressure control mechanism may include an exhaust mechanism to vacuum-exhaust the transfer chamber, a gas introducing mechanism to introduce gas to the transfer chamber, and a controller to control the exhaust mechanism and the gas introducing mechanism. The controller may control the exhaust through the exhaust mechanism and the gas introduction through the gas introducing mechanism to control the pressure within the transfer chamber. In this case, the gas introducing mechanism may include the purge-gas discharge member, and use the purge gas discharged from the purge-gas discharge member as the gas to be introduced for pressure control.

In the vacuum processing systems according to the first and second aspects, preferably, the purge-gas discharge member extends along a width direction of the loading/unloading hole and discharges the purge gas in a band shape. The purge-gas discharge member is preferably provided at a position lower than a transfer path of the to-be-processed substrate within the transfer chamber. The purge-gas discharge member preferably has a filter function. Preferably, the purge-gas discharge member is made of porous ceramics.

In the vacuum processing systems according to the first and second aspects, the processing chamber is a CVD processing chamber to perform CVD using a metal-halogen compound as a source material.

According to the present invention, the purge-gas discharge member is provided near the loading/unloading hole of the transfer chamber, and a purge gas is discharged from the purge-gas discharge member to the processing chamber via the loading/unloading hole in a state where the transfer chamber and the processing chamber are communicated with each other by opening of the gate valve. Thus, it is possible to introduce a high density purge gas to the processing chamber via the loading/unloading hole. Also, even if pollutants remain in the processing chamber, it is possible to effectively suppress back-diffusion of such pollutants into the transfer chamber.

### BRIEF DESCRIPTION OF THE DRAWINGS

FIG. 1 is a plan view showing a multi-chamber type vacuum processing system according to one embodiment of the present invention.

FIG. 2 is a cross-sectional view showing a transfer chamber in the vacuum processing system in FIG. 1.

FIG. 3 is a plan view showing a transfer chamber in the vacuum processing system in FIG. 1.

FIG. 4 is a mimetic diagram showing the position relation between a purge-gas discharge member and a loading/unloading hole within a transfer chamber.

FIG. 5 is a cross-sectional view showing a CVD processing chamber in the vacuum processing system in FIG. 1.

FIG. 6 is a mimetic diagram showing the state where a flow of purge gas from a transfer chamber to a CVD processing chamber is formed by the purge gas discharged from a purge-gas discharge member.

### DETAILED DESCRIPTION OF THE INVENTION

Hereinafter, exemplary embodiments of the present invention will be described in detail with reference to the accompanying drawings.

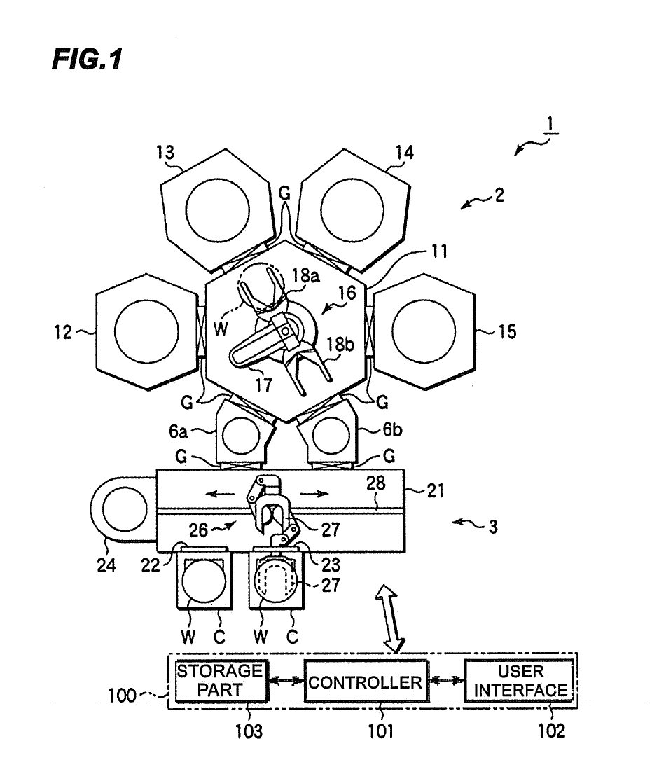

FIG. 1 is a plan view showing a multi-chamber type vacuum processing system according to one embodiment of the present invention.

A vacuum processing system 1 includes a processing unit 2 having a plurality of processing chambers to perform CVD processing, a loading/unloading unit 3, and load-lock chambers 6a and 6b between the processing unit 2 and the loading/unloading unit 3. The vacuum processing system 1 is configured to carry out the formation of a metallic film on a wafer W.

The processing unit 2 includes a transfer chamber 11 having a hexagonal planar shape, and four CVD processing chambers 12, 13, 14, and 15 connected to four sides of the transfer chamber 11. The load-lock chambers 6a and 6b are connected to two other sides of the transfer chamber 11, respectively. The CVD processing chambers 12 to 15 and the load-lock chambers 6a and 6b are connected to the sides of the transfer chamber 11, respectively, through gate valves G. The CVD processing chambers 12 to 15 and the load-lock chambers 6a and 6b are communicated with the transfer chamber 11 by opening corresponding gate valves G, and are blocked from the transfer chamber 11 by closing the corresponding gate valves G. A transfer mechanism 16 is provided within the transfer chamber 11. The transfer mechanism 16 loads/unloads wafers W in/from the CVD processing chambers 12 to 15 and the load-lock chambers 6a and 6b. The transfer mechanism 16 is disposed at nearly the center of the transfer chamber 11. Two support arms 18a and 18b for supporting the wafer W are provided at the leading end of a rotating/extending part 17 being rotatable and extendable. The two support arms 18a and 18b are attached to the rotating/extending part 17 in opposite directions. The inside of the transfer chamber 11 is maintained with a degree of vacuum, as described later.

The loading/unloading unit 3 includes a loading/unloading chamber 21 provided at an opposite side of the processing unit 2 across from the load-lock chambers 6a and 6b and connected to the load-lock chambers 6a and 6b. Gate valves G are provided between the load-lock chambers 6a and 6b and the loading/unloading chamber 21. Two connecting ports 22 and 23 are provided at a side of the loading/unloading chamber 21 opposite to the side connected to the load-lock chambers 6a and 6b. The two connecting ports 22 and 23 are connected to carriers C for receiving the wafer W as a to-be-processed substrate. Each of the connecting ports 22 and 23 is provided with a shutter (not shown). When the connecting ports 22 and 23 are directly attached to the carrier C receiving the wafer W or the empty carrier C, the shutter is separated to prevent the outside air from entering and the connecting ports 22 and 23 are communicated with the loading/unloading chamber 21. Also, an alignment chamber 24 is provided at the lateral side of the loading/unloading chamber 21. The wafer W is aligned in the alignment chamber 24. A loading/unloading transfer mechanism 26 for loading/unloading the wafer W in/from the carrier C and in/from the load-lock chambers 6a and 6b is provided within the loading/unloading chamber 21. The loading/unloading transfer mechanism 26 includes two multi-joint arms, and is configured to be movable on a rail 28 along an arrangement direction of the carriers C. The transfer mechanism loads the wafer W on a hand 27 at the leading end of each transfer mechanism, and then transfers the wafer W.

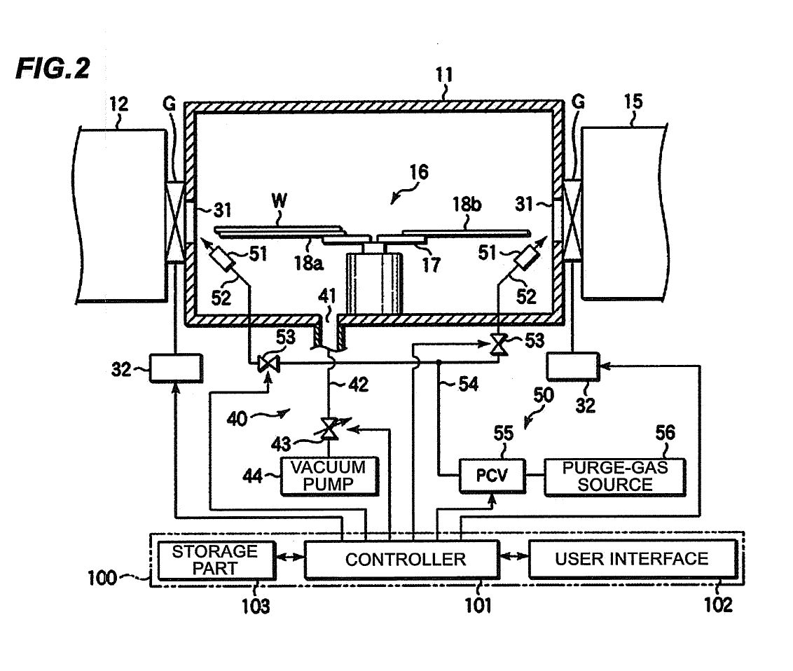

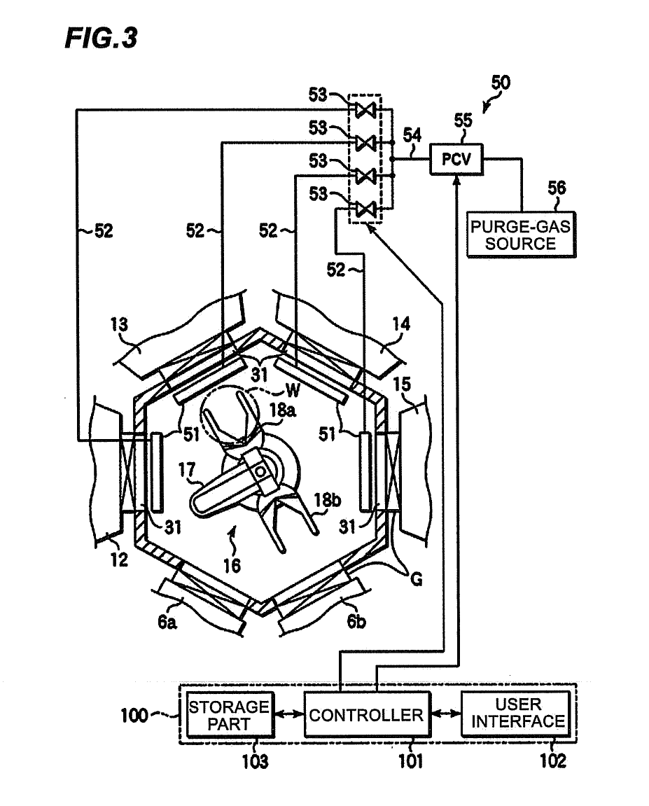

Hereinafter, the transfer chamber 11 will be described in detail. FIG. 2 is a cross-sectional view mimetically showing the transfer chamber 11 and FIG. 3 is a plan view of the transfer chamber 11. Loading/unloading holes 31 for loading/unloading the wafer W in/from the CVD processing chambers 12 to 15 are provided at the lateral walls of the transfer chamber 11. The loading/unloading holes 31 may be opened/closed by the gate valves G. Each gate valve G may be opened/closed by an actuator 32.

During the transfer of the wafer W to any one of the CVD processing chambers 12 to 15, the transfer chamber 11 is communicated with the CVD processing chamber as described above. Therefore, an exhaust mechanism 40 and a gas introducing mechanism 50 are provided at the transfer chamber 11 to adaptively control a pressure of the transfer chamber 11 to be suitable for the pressure of each CVD processing chamber. Specifically, the pressure of the transfer chamber 11 is adaptively controlled to be suitable for the pressure of the CVD processing chamber communicated with the transfer chamber 11 by controlling the exhaust through the exhaust mechanism 40 and the gas introduction through the gas introducing mechanism 50.

The exhaust mechanism 40 includes an exhaust pipe 42 connected to an exhaust outlet 41 provided at the bottom of the transfer chamber 11, an exhaust-rate adjusting valve 43 interposed in the exhaust pipe 42, and a vacuum pump 44 connected to the exhaust pipe 42. Also, during the control of the exhaust-rate adjusting valve 43, the transfer chamber 11 is degassed up to a specific pressure by the vacuum pump 44 via the exhaust pipe 42.

The gas introducing mechanism 50 includes purge-gas discharge members 51 each provided near the lower portion of the loading/unloading hole 31 of each processing chamber of the transfer chamber 11 to discharge purge gas, purge-gas pipes 52 each connected to the respective purge-gas discharge members 51, opening/closing valves 53 each interposed in the respective purge-gas pipes 52, a collective pipe 54 at which the purge-gas pipes 52 gather together, a pressure control valve (PCV) 55 interposed in the collective pipe 54, and a purge-gas source 56 connected to the collective pipe 54.

As shown in FIGS. 2 and 3, the purge-gas discharge member 51 extends along the longitudinal direction of the loading/unloding hole 31 at a position lower than a transfer path of a wafer W and has a length equal to or greater than the diameter of the wafer W. The purge-gas discharge member 51 is configured to discharge the purge gas in a band shape. The reason why the position is lower than the transfer path of the wafer W is to prevent particles from attaching to the wafer W. If there is no need to consider the attachment of particles, the purge-gas discharge members may be provided at a position higher than the transfer path of the wafer W.

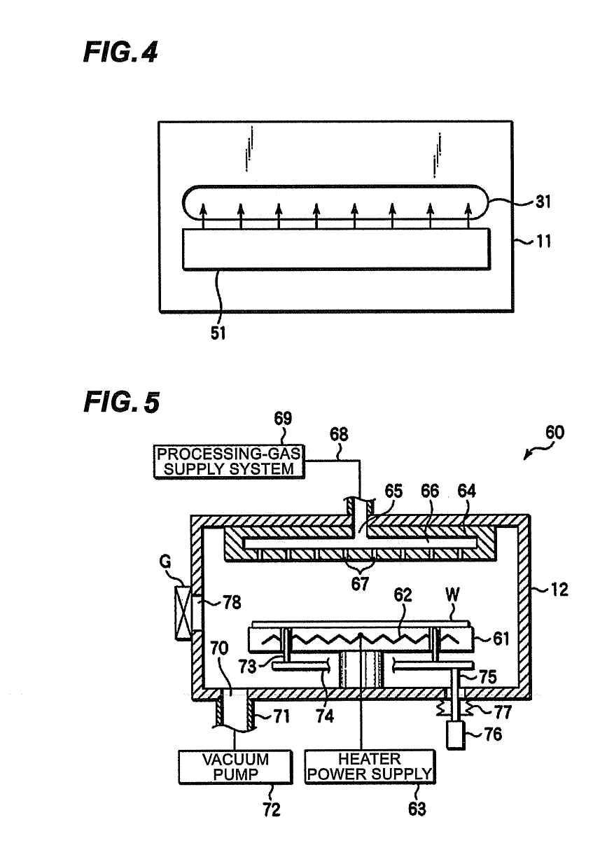

The purge-gas discharge members 51 have the functions of discharging purge gas to the CVD processing chambers 12 to 15 and discharging purge gas to adjust the pressure. As shown in FIG. 4, when the purge-gas discharge members 51 discharge purge gas (for example, Ar gas) toward the loading/unloading holes 31 and discharge purge gas to the CVD processing chambers 12 to 15, the gate valves G are opened to communicate the transfer chamber 11 with the CVD processing chambers and form the purge-gas flow toward the CVD processing chambers connected to the loading/unloading holes 31. In this case, the purge-gas discharge member 51 is preferably made of a material having a filtering function to form a uniform gas flow and prevent particles from being introduced. For example, porous ceramics may be used as the material having the filtering function.

In order to control the pressure of the transfer chamber 11 by using the exhaust mechanism 40 and the gas introducing mechanism 50, the gate valve G is opened to communicate the transfer chamber 11 with the specific CVD processing chamber and a controller 101, as described later, controls the exhaust-rate adjusting valve 43 and the pressure control valve 55, thereby controlling the exhaust through the exhaust mechanism 40 and the gas introduction through the gas introducing mechanism 50, so that the pressure of the transfer chamber 11 is adaptively adjusted to be suitable for the pressure of the CVD processing chamber. Herein, the purge-gas discharge member 51 has a function of adjusting the pressure within the transfer chamber 11 by the discharge of the purge gas.

Hereinafter, the CVD processing chamber 12 of the processing unit 2 will be described with reference to the cross-sectional view of FIG. 5. The CVD processing chamber 12 constitutes a portion of a CVD processing apparatus 60, and performs CVD processing therein. In other words, a support table 61 on which a wafer W is supported is provided within the CVD processing chamber 12 constituting a portion of the CVD processing apparatus 60, and a heater 62 is provided within the support table 61. The heater 62 is energized by a heater power supply 63 to provide heat.

The upper wall of the CVD processing chamber 12 is provided with a shower head 64 to introduce a processing gas for CVD processing into the CVD processing chamber 12 in a shower form. The shower head 64 faces the support table 61. The shower head 64 includes a gas introducing hole 65 in the upper portion thereof, a gas diffusion space 66 formed therewithin, and a plurality of gas discharge holes 67 at the bottom surface thereof. The gas introducing hole 65 is connected to a gas supply pipe 68. The gas supply pipe 68 is connected to a processing-gas supply system 69 for supplying a processing gas for CVD processing, in other words, a source material gas for forming a thin film through reaction. Accordingly, the processing gas may be supplied from the processing-gas supply system 69 into the CVD processing chamber 12 via the gas supply pipe 68 and the shower head 64. An exhaust hole 70 is formed at the bottom of the CVD processing chamber 12, and connected to an exhaust pipe 71. Also, a vacuum pump 72 is provided at the exhaust pipe 71. The inside of the CVD processing chamber 12 is maintained at 1×10¹ to 1×10³ Pa (approximately 1×10⁻¹ to 1×10¹ Torr) by supplying the processing gas and operating the vacuum pump 72.

The support table 61 is provided with three wafer supporting pins 73 (only two of them are shown) for wafer transfer. The wafer supporting pins 73 are able to protrude and retract with respect to the surface of the support table 61, and are fixed on a support plate 74. Also, the wafer supporting pins 73 are moved up and down through the support plate 74 by moving a rod 75 up and down through a driving mechanism 76, such as an air cylinder. Also, the reference numeral 77 indicates a bellows. Meanwhile, a wafer loading/unloading port 78 is formed at the lateral wall of the CVD processing chamber 12, and a wafer W is loaded/unloaded from/into the transfer chamber 11 while the gate valve G is opened.

While the inside of the CVD processing chamber 12 is exhausted by the vacuum pump 72, the processing gas is introduced from the processing-gas supply system 69 into the CVD processing chamber 12 via the gas supply pipe 68 and the shower head 64 in a state where the wafer W is heated up to a temperature by the heater 62 via the support table 61. Then, the reaction of the processing gas on the wafer W progresses, and a thin film is formed on the surface of the wafer W. Plasma may be formed as an appropriate means for promoting the reaction.

For example, the CVD processing performed within the CVD processing chamber 12 may be a film formation using a metal halogen compound, such as a Ti film, a TiN film, a W film, a WSi film, or the like, as a source material gas. The CVD processing is for forming a film on the wafer by creating a chemical reaction of the source material gas on the wafer. For example, although a Ti film is formed by reducing TiCl₄ gas with H₂ gas, the ratio of gas participating in the reaction is small, and pollutants, such as unreacted gas or by-product gas, are generated in a large amount and remain within the processing chamber.

Also, the CVD processing chambers 13 to 15 basically have the same structure as that of the CVD processing chamber 12.

The load-lock chambers 6a and 6b are for transferring the wafer W between the loading/unloading chamber 21 with air atmosphere and the transfer chamber 11 with vacuum atmosphere. Each of the load-lock chambers includes an exhaust mechanism and a gas supply mechanism (both not shown), and is configured to convert the inside thereof into air atmosphere or vacuum atmosphere appropriate suitable for the transfer chamber 11 in a short time. Also, when the wafer W is transferred from/to the loading/unloading chamber 21, each of the load-lock chambers is communicated with the loading/unloading chamber 21 after the conversion from the sealed state into air atmosphere. When the wafer W is transferred from/to the transfer chamber 11, each of the load-lock chambers is communicated with the transfer chamber 11 after the conversion from the sealed state into vacuum atmosphere.

The vacuum processing system 1 has a control unit 100 to control respective components. The control unit 100 includes the controller 101, a user interface 102, and a storage part 103. The controller 101 includes a microprocessor (computer) to perform the control of respective components. The user interface 102 includes a keyboard through which an operator inputs commands, etc. to manage the vacuum processing system 1, a display to visualize and show the operating state of the vacuum processing system 1, and the like. The storage part 103 stores a processing recipe, such as a control program for allowing the vacuum processing system 1 to perform various processes under the control of the controller 101 or a program for performing processes in the respective components of the processing apparatus according to various data and processing conditions. Also, the user interface 102 and the storage part 103 are connected to the controller 101.

The processing recipe is recorded in a storage medium within the storage part 103. The storage medium may be a hard disk, or a transferable-type medium, such as CDROM, DVD, flash memory, etc. Also, the recipe may be appropriately transmitted from another device, for example, via a dedicated line.

Also, any processing recipe, as required, is called from the storage part 103 in accordance with the instruction, etc. from user interface 102, and is executed in the controller 101, thereby performing a required process in the vacuum processing system 1 under the control of the controller 101.

Especially, in the present embodiment, as shown in FIGS. 2 and 3, the controller 101 controls the actuators 32 of the gate valves G, the opening/closing valves 53 or the pressure control valve 55 of the gas introducing mechanism 50, and the exhaust-rate adjusting valve 43 of the exhaust mechanism 40, and thereby controls the opening/closing of the gate valves, and the pressure and gas flow of the transfer chamber 11 when the wafer W is loaded/unloaded to/from any one of the CVD processing chambers.

Hereinafter, the processing operation in such a vacuum processing system 1 will be described.

In the vacuum processing system 1, the CVD processing chambers 12 to 15 may be for forming a single film (homogeneous film), or may be for forming a plurality of kinds of films (for example, a layered film of a Ti film and a TiN film). In the latter case, for example, the CVD processing chambers 12 and 13 may be used for forming the Ti film and the CVD processing chambers 14 and 15 may be used for forming the TiN film.

In the film formation, first, a wafer W is drawn out from any one carrier C by the loading/unloading transfer mechanism 26 and is loaded into the load-lock chamber 6a. Then, the load-lock chamber 6a is sealed and vacuum-exhausted to the same level of a pressure as that of the transfer chamber 11. Next, the gate valve G at the transfer chamber 11 side is opened and the wafer W in the load-lock chamber 6a is drawn out into the transfer chamber 11 by the transfer mechanism 16. Then, by the exhaust mechanism 40 and the gas introducing mechanism 50, the pressure of the transfer chamber 11 is controlled to be a pressure suitable for one chamber, to which the wafer W is to be loaded, from among the CVC processing chambers 12 to 15 and the gate valve G corresponding to the CVD processing chamber is opened to allow the wafer W to be loaded into the CVD processing chamber via the loading/unloading hole 31. In the chamber, a CVD film-forming process, such as a formation of Ti film, is performed.

After the completion of the CVD film-forming process, in the case of the formation of a single film, the gate valve G corresponding to the CVD processing chamber which has been used for the process is opened and the wafer W is drawn out from the CVD processing chamber to the first transfer chamber 11 by the transfer mechanism 16. Then, the wafer W is loaded into the load-lock chamber 6b, the inside of the load-lock chamber 6b is adjusted to atmosphere pressure, and then the wafer W is received in any one of the carriers C by the loading/unloading transfer mechanism 26.

In the case of the formation of a double-layered film, after the completion of the CVD film formation in the CVD processing chamber, the gate valve corresponding to the CVD processing chamber is opened and the wafer W is drawn out from the CVD processing chamber to the first transfer chamber 11 by the transfer mechanism 16. Then, another gate valve G corresponding to another CVD processing chamber which will perform a following film formation is opened and another film different from the first formed film, for example, a TiN film, is formed within the another CVD processing chamber. Also, in the case of a triple or more layered film, the film formation process is repeatedly performed in the further CVD processing chamber in the same manner as described above. Finally, the gate valve G corresponding to the final CVD processing chamber is opened and the wafer W is drawn out by the transfer mechanism 16 from the CVD processing chamber to the first transfer chamber 11. Then, the wafer W is loaded into the load-lock chamber 6b, the inside of the load-lock chamber 6b is adjusted to atmosphere pressure, and then the wafer W is received in any one of the carriers C by the loading/unloading transfer mechanism 26.

However, as described above, the CVD processing is for forming a film on the wafer by creating a chemical reaction of the source material gas on the wafer. Thus, in the formation of a Ti film, a TiN film, or the like, pollutants, such as unreacted gas or by-product gas, may remain in a large amount within the chamber. Besides, the inside of the chamber is maintained with a relatively high pressure of 1×10¹ to 1×10³ Pa (approximately 1×10⁻¹ to 1×10¹ Torr). Thus, if the pollutants (contamination) are back-diffused into the transfer chamber 11 by the opening of the gate valve G, cross-contamination between the transfer chamber and another CVD processing chamber may be caused.

According to a conventional technology, in order to suppress such a back-diffusion of pollutants, gas is introduced from a single portion of the transfer chamber 11 to maintain a pressure within the transfer chamber slightly higher than that of one processing chamber, that is to be communicated with the transfer chamber, from among the CVD processing chambers 12 to 15 and a gas flow from the transfer chamber 11 toward the CVD processing chamber is formed when the gate valve is opened to load/unload a wafer to/from the CVD processing chamber, thereby suppressing the back-diffusion from the CVD processing chamber to the transfer chamber 11.

However, in such a technology, the number of gas supply port for supplying gas toward the transfer chamber 11 is only one. Accordingly, when a to-be-used CVD processing chamber and the transfer chamber 11 are communicated with each other by opening the gate valve G therebetween, the flow of purge gas from the transfer chamber to the CVD processing chamber has a low density, and also is likely to be non-uniform. Thus, the back-diffusion of pollutants from the communicated CVD processing chamber to the transfer chamber 11 may be insufficiently suppressed.

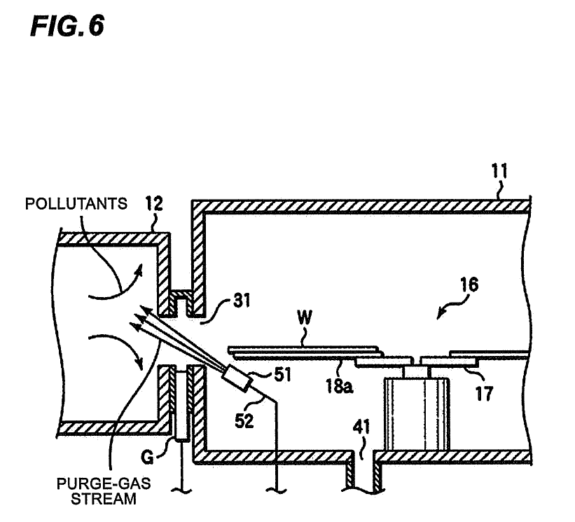

Therefore, in the present embodiment, the purge-gas discharge member is provided near each CVD processing chamber, specifically, near the loading/unloading hole 31 communicating with each CVD processing chamber, and a purge gas is discharged toward the loading/unloading hole 31 from the purge-gas discharge member 51 corresponding to the CVD processing chamber communicated with the transfer chamber 11. As described above, since the purge-gas discharge member 51 for discharging a purge gas is provided near the loading/unloading hole 31, the purge gas discharged from the purge-gas discharge member 51, as shown in FIG. 6, may form a high density gas flow from the transfer chamber 11 toward the CVD processing unit communicated to the transfer chamber 11 (the CVD processing unit 12 in the example of FIG. 6), thereby effectively suppressing the back-diffusion of pollutants from the CVD processing chamber. Also, since the purge-gas discharge member 51 extends along the longitudinal direction of the loading/unloading hole 31 and has a length equal to or greater than the diameter of a wafer W, it is possible to form a uniform purge-gas flow from the transfer chamber 11 toward the CVD processing chamber and to more securely suppress the back-diffusion of pollutants.

Also, since the purge-gas discharge member 51 is provided to each of the CVD processing chambers 12 to 15 to be capable of selectively discharging a purge gas by the switch of the valve, it is possible to form a purge gas within only a required CVD processing chamber that is communicated to the transfer chamber and requires the suppressing of back-diffusion of pollutants.

Preferably, the pressure of the transfer chamber 11 is maintained to be higher than that of the communicated transfer chamber from among the CVD processing chambers 12 to 15 by the exhaust mechanism 40 and the gas introducing mechanism 50. Accordingly, it is possible to more effectively suppress the back-diffusion of pollutants.

Moreover, a material having a filter function, such as porous ceramics, may be used as the purge-gas discharge member 51 to form a more uniform gas flow, and prevent the introduction of particles.

Also, the present invention is not limited to the above-described embodiment and various modifications may be made within the scope of the present invention. For example, although four CVD processing chambers are provided in the transfer chamber in the above-described embodiment, the number of CVD processing chambers is not limited to four and one or more processing chambers may be used. Also, although a purge-gas discharge member extends along the loading/unloading hole in the above-described embodiment, the present invention is not limited thereto. For example, the purge-gas discharge member may be a ring-shaped so that a uniform gas flow toward the loading/unloading hole can be obtained.

Also, although the purge-gas discharge members are provided to all of the CVD processing chambers in the above-described embodiment, the present invention is not limited thereto. The gas discharge member may be provided to only specific CVD processing chamber.

Moreover, although a CVD film formation process is performed as a vacuum processing in the above-described embodiment, the present invention is not limited thereto and other vacuum processes may be performed.

What is claimed is:

1. A vacuum processing system comprising:
a processing chamber to perform predetermined processes on a to-be-processed substrate under a vacuum;
a transfer chamber having a loading/unloading hole to load/unload the to-be-processed substrate and being connected to the processing chamber via a gate valve capable of opening/closing the loading/unloading hole, the inside of the transfer chamber being maintained in a vacuum state;
a transfer mechanism provided within the transfer chamber to load/unload the to-be-processed substrate to/from the processing chamber via the loading/unloading hole; and
a purge-gas discharge member provided near the loading/unloading hole to discharge a purge gas to the processing chamber via the loading/unloading hole in a state where the transfer chamber and the processing chamber are communicated with each other by opening of the gate valve.

2. The vacuum processing system of claim 1, further comprising a pressure control mechanism to control a pressure of the transfer chamber,
wherein the pressure control mechanism controls the pressure of the transfer chamber to be a pressure suitable for the processing chamber.

3. The vacuum processing system of claim 2, wherein the pressure control mechanism controls the pressure of the transfer chamber to be higher than the pressure of the processing chamber.

4. The vacuum processing system of claim 2, wherein the pressure control mechanism comprises an exhaust mechanism to vacuum-exhaust the transfer chamber, a gas introducing mechanism to introduce gas to the transfer chamber, and a controller to control the exhaust mechanism and the gas introducing mechanism, and
wherein the controller controls the exhaust by the exhaust mechanism and the gas introduction by the gas introducing mechanism to control the pressure within the transfer chamber.

5. The vacuum processing system of claim 4, wherein the gas introducing mechanism comprises the purge-gas discharge member, and uses the purge gas discharged from the purge-gas discharge member as the gas to be introduced for pressure control.

6. The vacuum processing system of claim 1, wherein the purge-gas discharge member extends along a width direction of the loading/unloading hole and discharges the purge gas in a band shape.

7. The vacuum processing system of claim 1, wherein the purge-gas discharge member is provided at a position lower than a transfer path of the to-be-processed substrate within the transfer chamber.

8. The vacuum processing system of claim 1, wherein the purge-gas discharge member has a filter function.

9. The vacuum processing system of claim 8, wherein the purge-gas discharge member is made of porous ceramics.

10. The vacuum processing system of claim 1, wherein the processing chamber is a CVD processing chamber to perform CVD using a metal-halogen compound as a source material.

11. A vacuum processing system comprising:
a plurality of processing chambers to perform predetermined processes on a to-be-processed substrate under a vacuum;
a transfer chamber having a plurality of loading/unloading holes to load/unload the to-be-processed substrate, each loading/unloading hole being connected with each processing chamber via a gate valve capable of opening/closing said loading/unloading hole, an inside of the transfer chamber being maintained in a vacuum state;
a transfer mechanism provided within the transfer chamber to selectively load/unload the to-be-processed substrate to/from any one of the processing chambers via any one of the loading/unloading holes;
a plurality of purge-gas discharge members each provided near each loading/unloading hole to discharge a purge gas toward the corresponding loading/unloading hole; and
a control unit to control the purge-gas discharge members so that, in a state where the transfer chamber and said one of the processing chambers are communicated with each other by opening of any one gate valve, the purge gas is discharged from the purge-gas discharge member corresponding to the communicated processing chamber toward the communicated processing chamber via the corresponding loading/unloading hole.

12. The vacuum processing system of claim 11, further comprising a pressure control mechanism to control a pressure of the transfer chamber,
wherein the pressure control mechanism controls the pressure of the transfer chamber to be a pressure suitable for the communicated processing chamber of the processing chambers.

13. The vacuum processing system of claim 12, wherein the pressure control mechanism controls the pressure of the transfer chamber to be higher than the pressure of the communicated processing chamber of the processing chambers.

14. The vacuum processing system of claim 12, wherein the pressure control mechanism comprises an exhaust mechanism to vacuum-exhaust the transfer chamber, a gas introducing mechanism to introduce gas to the transfer chamber, and a controller to control the exhaust mechanism and the gas introducing mechanism, and
wherein the controller controls the exhaust by the exhaust mechanism and the gas introduction by the gas introducing mechanism to control the pressure within the transfer chamber.

15. The vacuum processing system of claim 14, wherein the gas introducing mechanism comprises the purge-gas discharge members, and uses the purge gas discharged from the purge-gas discharge members as the gas to be introduced for pressure control.

16. The vacuum processing system of claim 11, wherein each purge-gas discharge member extends along a width direction of each loading/unloading hole, and discharges the purge gas in a band shape.

17. The vacuum processing system of claim 11, wherein the purge-gas discharge members are provided at positions lower than a transfer path of the to-be-processed substrate within the transfer chamber.

18. The vacuum processing system of claim 11, wherein each purge-gas discharge member has a filter function.

19. The vacuum processing system of claim 18, wherein each purge-gas discharge member is made of porous ceramics.

20. The vacuum processing system of claim 11, wherein each processing chamber is a CVD processing chamber to perform CVD using a metal-halogen compound as a source material.
